(19) United States
(12) Patent Application Publication
(10) Pub. No.: US 2013/0187158 A1
(43) Pub. Date: Jul. 25, 2013

(54) SEMICONDUCTOR DEVICE

(71) Applicant: Toshimitsu TANIGUCHI, Ota-shi (JP)

(72) Inventor: Toshimitsu TANIGUCHI, Ota-shi (JP)

(21) Appl. No.: 13/745,286

(22) Filed: Jan. 18, 2013

(30) Foreign Application Priority Data
Jan. 20, 2012 (JP) 2012-009973
May 8, 2012 (JP) 2012-106775

(51) Int. Cl. H01L 23/544

(52) U.S. Cl. CPC H01L 23/544
USPC 257/48

(57) ABSTRACT

The invention prevents a short circuit between bonding wires, between device pads, or between the bonding wire and the device pad due to a cut residue portion of a scribe TEG pad coming off from an end portion of a semiconductor chip. A scribe TEG pad on a semiconductor wafer is formed of a plurality of rectangular pads each extending on a scribe line toward a device forming region. The semiconductor wafer is divided into semiconductor chips by dicing. At this time, the length of each of cut residue portions of the scribe TEG pad remaining on an end portion of the semiconductor chip is shorter than an interval between the end portions of openings of a passivation film on adjacent device pads.

### CROSS-REFERENCE OF THE INVENTION

This application claims priority from Japanese Patent Application No. 2012-009973, filed Jan. 20, 2012, and No. 2012-106775, filed May 8, 2012, the content of which is incorporated herein by reference in its entirety.

### BACKGROUND OF THE INVENTION

1. Field of the Invention

The invention relates to a semiconductor device, in particular, a semiconductor device that prevents a cut residue portion of a scribe TEG pad remaining on an end portion of a semiconductor chip from causing a short circuit between bonding wires etc when a semiconductor wafer is divided into individual semiconductor chips by dicing.

2. Description of the Related Art

In recent years, with the progression of miniaturization, a larger-scale integrated semiconductor device with higher density is being developed, and the function is highly progressed by being provided with various types of circuit functions etc. Thus, for process monitoring, defect analysis, etc, a test element group (TEG) has an essential role as an evaluation element that accurately detects the characteristics of a basic device or a basic circuit. The number of TEG is increasing with the progression of density and function of a semiconductor device.

The occupation area of such a TEG in a semiconductor substrate is not so small. A TEG for basic characteristic evaluation in a semiconductor wafer state obtains evaluation data at the time when a semiconductor wafer is completed, and thus the purpose is achieved at the time. Therefore, a TEG for this purpose is provided on a scribe line that is to be removed by dicing a semiconductor substrate into individual semiconductor chips, achieving the effective utilization of a semiconductor substrate. In the following description, a TEG provided on a scribe line is called a scribe TEG.

As described above, a semiconductor wafer that completes a front-end process is divided into individual semiconductor chips by dicing along a scribe line. In other words, a scribe line has a role of assembling individual semiconductor chips until the semiconductor wafer is completed. The scribe line then becomes a region to be removed by dicing. It is thus preferable that a scribe line has as small width as possible, but employing a scribe TEG leads to an increase of the width of the scribe line.

In Japanese Patent Application publication No. 2003-332397, a scribe TEG pad that is the topmost layer of a scribe TEG and a foundation region for forming an electrode are overlapped as much as possible so as to decrease the occupation area of the scribe TEG in a scribe line.

Japanese Patent Application publication No. Hei 08-138999 discloses using a mask alignment target for preventing the size increase of a scribe TEG.

In Japanese Patent Application publication No. 2006-120896, although this is a particular case, a scribe TEG is not used and the width of a scribe line is decreased so as to decrease a difference between the high frequency characteristic of a semiconductor device after a front-end process and the high frequency characteristic of the semiconductor device after a post-process and so as to keep the reliability of the electric characteristic etc of a completed product.

As described above, Japanese Patent Application publication Nos. 2003-332397 and Hei 08-138999 disclose utilizing a semiconductor substrate effectively by decreasing the size of a scribe TEG as much as possible. Even in these cases, the scribe TEG pad that is the topmost layer of the scribe TEG need have a predetermined size. This is because it is necessary to properly connect a characteristic measurement probe having a predetermined cross section to the scribe TEG pad.

As a result, as described above, since the width of a scribe line is designed to be as small as possible for the effective utilization of a semiconductor substrate, the width of a scribe TEG pad 33 that is perpendicular to a scribe line 31 almost occupies the width of the scribe line 31 as shown in an enlarged plan view of a main portion near a scribe line in FIG. 4A. For example, the width of the scribe TEG pad that is perpendicular to the scribe line 31 is set to 90% or more of the width of the scribe line.

The scribe TEG pad 33 is made of a metal thin film of aluminum (Al) etc. Ordinarily the thickness is about 1 μm, but, in a case of a power device etc through which a relatively large current flows, the thickness is about several μm. The scribe TEG pad 33 is a TEG characteristic measurement pad, and is disposed as the topmost layer of multi-layered wires without being covered by a passivation film.

FIG. 4A shows a device forming region 32 and device pads 34 formed in the device forming region 32. The device forming region 32 is covered by a passivation film 40. Openings 40a are formed in the passivation film 40, exposing a portion of each of the device pads 34.

The scribe line 31 is formed between the upper and lower device forming regions 32 as shown in FIG. 4A, and a scribe TEG forming region 51 lies in a partial region of the scribe line 31. The passivation film 40 is removed on the scribe line. This is because the passivation film 40 made of a silicon nitride film etc is hard and fragile, and cracks easily occur therein under stress applied by dicing.

The plurality of scribe TEG pads 33 are formed on the surface of the scribe TEG forming region 51. However, for only understanding the substance of the invention, FIG. 4A simply shows only one scribe TEG pad 33 for one scribe TEG forming region 51.

FIG. 4B is a cross-sectional view of FIG. 4A along line A-A, and the scribe TEG pad 33 is connected to a lower electrode 36 through plug electrodes 35 made of tungsten (W) etc filling via holes formed in an interlayer insulation film 37. In many cases, the scribe TEG pad 33 is connected to the lower electrode 36 directly through the via holes. The lower electrode 36 is formed on an interlayer insulation film 38, having the equivalent size to the scribe TEG pad 33.

FIG. 4C is a cross-sectional view of FIG. 4A along line B-B. The scribe TEG pad 33 and the device pad 34 are formed on the same interlayer insulation film 37, opposing each other. FIG. 4D is a cross-sectional view of FIG. 4A along line C-C.

A plurality of semiconductor chips are formed on a semiconductor wafer 50 that completes a front-end process. Each of the semiconductor chips is judged as good or defective in its electric characteristic by a tester, and the process data are collected or the like by the scribe TEG. Dicing is then performed along the scribe line 31 to divide the semiconductor wafer 50 into the individual semiconductor chips 52 of which the main portion near the scribe line 31 is shown in an enlarged plan view in FIG. 5A. While the dicing width is determined depending on the width of a dicing blade, the dicing width is smaller than the width of the scribe line 31. This is because, when the dicing width is equal to the width of the scribe line 31, stress or deformation by dicing may reach the device forming region 32 and affect the device characteristics etc.

As a result, as shown in FIG. 5A, a portion of the scribe TEG pad 33 remains on an end portion of the divided semiconductor chip 52. Since the cut residue portion 33a of the scribe TEG pad 33 lies close to the dicing region, as shown in FIG. 5B that is a cross-sectional view of FIG. 5A along line D-D, the interlayer insulation film 37 under the cut residue portion 33a becomes a deformation layer 39 that is deformed by dicing. Therefore, the cut residue portion 33a remains on the deformation layer 39 that is unstable and destructible by various stresses.

Furthermore, since the width of the cut residue portion 33a of the scribe TEG pad 33 that extends from the dicing region toward the device forming region 32 is small, the cut residue portion 33a does not have an enough area to adhere to the interlayer insulation film 37 thereunder. Therefore, the cut residue portion 33a of the scribe TEG pad 33 having the small width that remains on the unstable deformation layer 39 deformed by dicing has a structure of easily coming off from the end portion of the semiconductor chip 52 even under small stress.

In particular, in a case of a power device, as described above, in the similar manner to the case of the device pad 34, the thickness of the scribe TEG pad 33 is several μm and thick, and thus the cut residue portion 33a of the scribe TEG pad 33 applies larger stress to the unstable deformation layer 39 than in the case of the scribe TEG pad 33 having an ordinary thickness. As a result, the cut residue portion 33a of the scribe TEG pad 33 has a structure of coming off from the end surface of the semiconductor chip 52 more easily than in the case of the scribe TEG pad 33 having an ordinary thickness of about 1 μm.

Therefore, when the device pad 34 of the semiconductor chip 52 and a lead frame or the like are wire-bonded by a gold wire etc or the like in a post-process, as shown in FIG. 6A and FIG. 6B that is a cross-sectional view of FIG. 6A along line F-F, the cut residue portion 33a of the scribe TEG pad 33 that comes off from the end portion of the semiconductor chip 52 may contact the bonding wire 41 or the device pad 34 partially exposed from the opening 40a of the passivation film 40, as a whiskerlike aluminum piece.

The cut residue portion 33a of the scribe TEG pad 33 that comes off from the end portion of the semiconductor chip 52 may cause a short circuit between the bonding wires 41, between the different device pads 34, or between the bonding wire 41 and the device pad 34, or may bring these to an easy short circuit state. This may result in a decrease of the yield of completed semiconductor devices, and may cause a problem in the long range reliability.

It is necessary to prevent various problems due to this cut residue portion 33a of the scribe TEG pad 33 coming off from the end portion of the semiconductor chip 52 as a whiskerlike aluminum piece.

### SUMMARY OF THE INVENTION

The invention provides a semiconductor device including: a semiconductor chip including a plurality of device pads; a cut residue portion of a scribe TEG pad that remains on an end portion of the semiconductor chip and comes off from the end portion; and a bonding wire connected to the device pad, in which the cut residue portion does not cause a short circuit between the adjacent device pads directly or through the bonding wire.

### BRIEF DESCRIPTION OF THE DRAWINGS

FIGS. 1A, 1B, 1C and 1D are an enlarged plan view and enlarged cross-sectional views of a main portion of scribe TEG pads formed on a scribe line and device pads in a semiconductor wafer state in an embodiment of the invention.

FIGS. 2A, 2B and 2C are an enlarged plan view and an enlarged cross-sectional view of a main portion of cut residue portions of the scribe TEG pads and the device pads, and an enlarged plan view of the main portion showing the cut residue portion of the scribe TEG pads that comes off and adheres to the vicinity of the wire-bonded device pads in the semiconductor chip in the embodiment of the invention.

FIGS. 3A and 3B are enlarged plan views of a main portion each showing a shape of a scribe TEG pad as a modification of the embodiment of the invention.

FIGS. 4A, 4B, 4C and 4D are an enlarged plan view and enlarged cross-sectional views of a main portion of scribe TEG pads formed on a scribe line and device pads on a semiconductor wafer in a conventional art.

FIGS. 5A, 5B and 5C are an enlarged plan view and enlarged cross-sectional views of a main portion of cut residue portions of the scribe TEG pads and the device pads on a semiconductor chip in the conventional alt

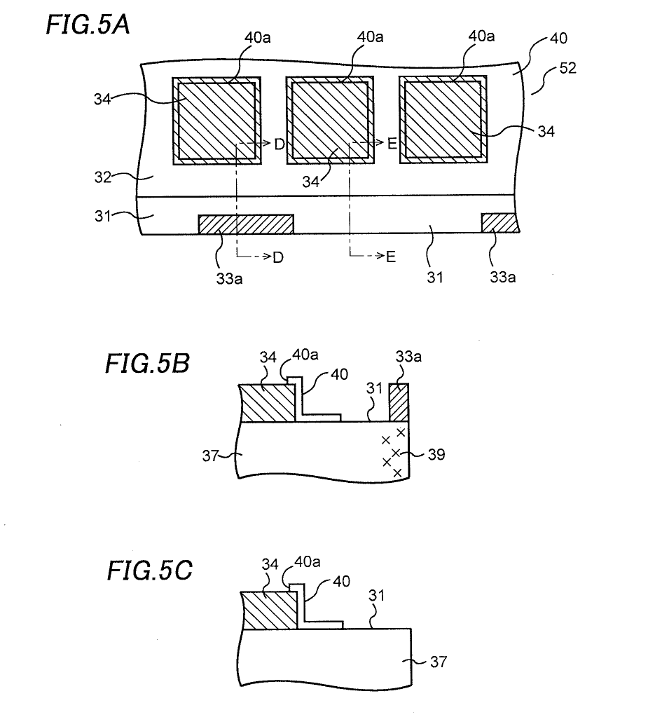

FIGS. 6A and 6B are an enlarged plan view and an enlarged cross-sectional view of the main portion showing the cut residue portion of the scribe TEG pad that comes off and adheres to the wire-bonded device pads in the conventional art.

### DETAILED DESCRIPTION OF THE INVENTION

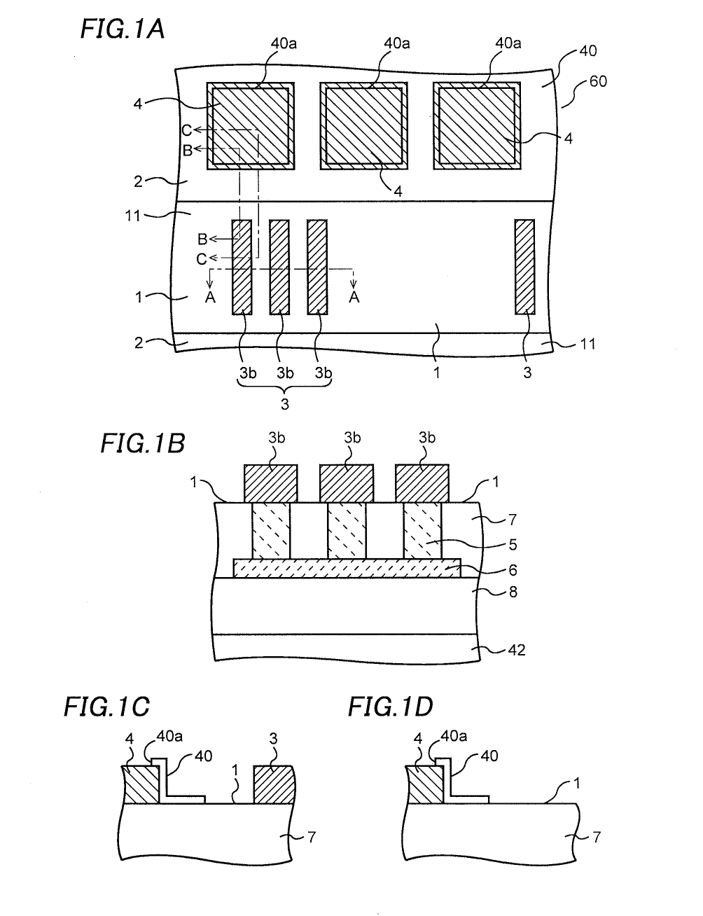

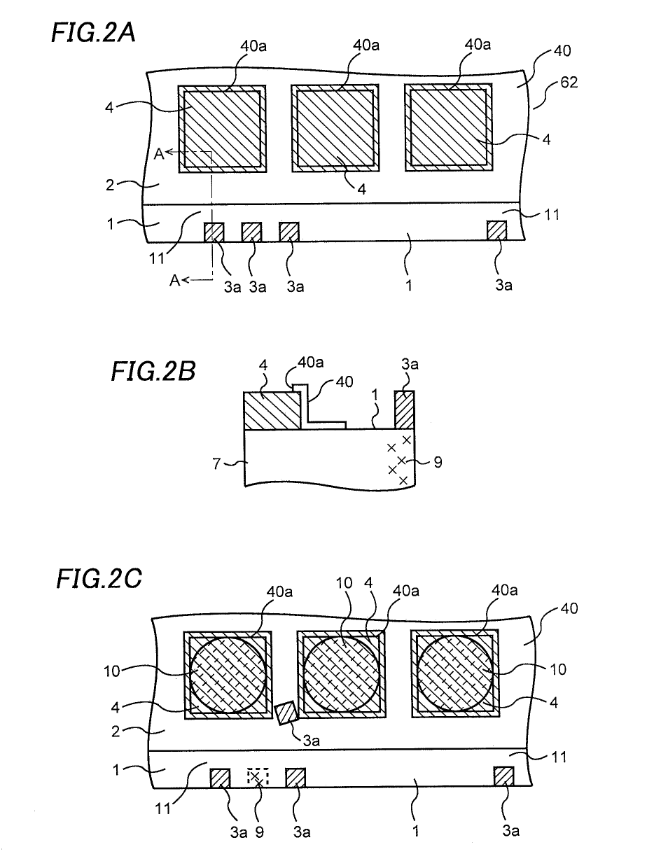

An embodiment of the invention will be described referring to FIGS. 1A to 2C. FIG. 1A is an enlarged plan view of a main portion adjacent to a scribe line 1 in a semiconductor wafer 60 state, schematically showing a relation of the positions of a scribe TEG forming region 11 formed on the scribe line 1 between two device forming regions 2, a scribe TEG pad 3 thereon, and device pads 4 formed in the device forming region 2.

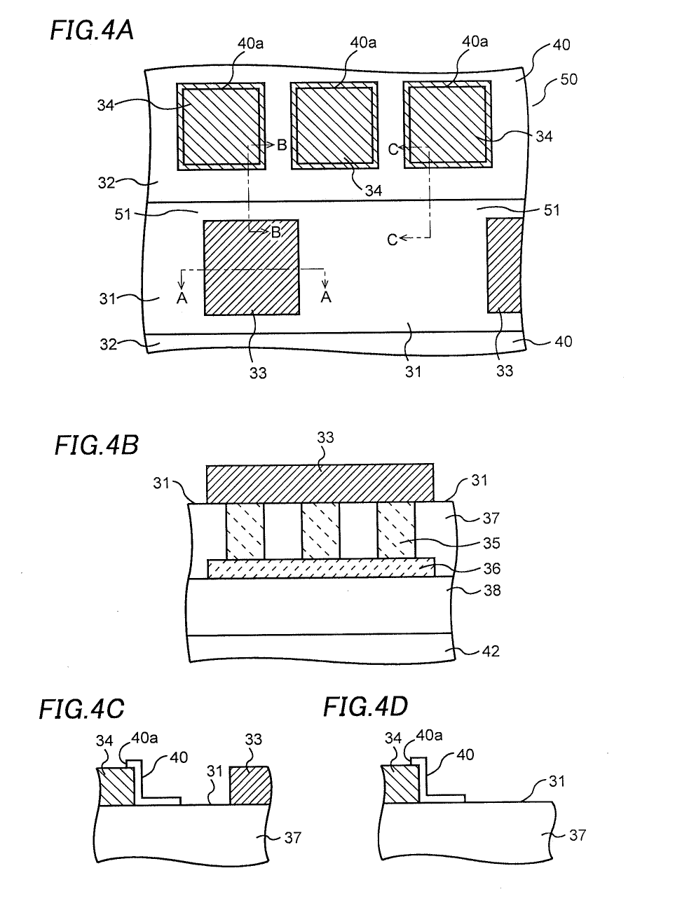

Although a plurality of scribe TEG pads 3 are formed in the scribe TEG forming region 11, as described above, for only understanding of the substance of the invention, one of the scribe TEG pads 3 is shown as an assembly of a plurality of oblong rectangular pads 3b. The feature of the embodiment is that the scribe TEG pad 3 is formed as the assembly of the oblong rectangular pads 3b each of which the length parallel with the scribe line 1 is short, different from FIG. 4A showing a conventional square structure.

FIG. 1B is a cross-sectional view of FIG. 1A along line A-A. The plurality of rectangular pads 3b forming the scribe TEG pad 3 are connected to a common lower electrode 6 foamed on an interlayer insulation film 8 through plug electrodes 5 made of tungsten (W) etc filling a plurality of via holes formed in an interlayer insulation film 7. In detail, the plurality of rectangular pads 3b forming the scribe TEG pad 3 are electrically connected to each other through the lower electrode 6. Alternatively, the rectangular pads 3b and the lower electrode 6 may be directly connected through the via holes without through the plug electrodes 5.

FIG. 1C is a cross-sectional view of FIG. 1A along line B-B. The scribe TEG pad 3 and the device pad 4 are formed on the flush interlayer insulation film 7, opposing each other. These thicknesses and film qualities are also the same. FIG. 1D is a cross-sectional view of FIG. 1A along line C-C. A space between the plurality of rectangular pads 3b is covered by the interlayer insulation film 7, and forms a portion of the scribe TEG forming region 11.

A plurality of semiconductor chips are formed on the semiconductor wafer 60. The device characteristic of each of the semiconductor chips is measured by connecting a probe to each of the device pads 4. Furthermore, similarly, the TEG characteristic is measured by the scribe TEG pad 3. Although the scribe TEG 3 is formed of the plurality of divided rectangular pads 3b, as described above, these are electrically connected through the lower electrode 6.

Therefore, even when a current to be measured is large, the measurement evaluation of the TEG characteristic is achieved by connecting a probe of which the tip is processed flat to the divided rectangular pads 3b. Furthermore, even when the probe is not connected to any one of the rectangular pads 3b as a whole, a problem in measurement evaluation does not occur since the rectangular pads 3b are connected to the common lower electrode 6 thereunder through the plurality of plug electrodes 5.

FIG. 2A is an enlarged plan view of a main portion showing a region adjacent to the scribe line 1 in one of a plurality of semiconductor chips 62 cut and divided by dicing the semiconductor wafer 60 along the scribe line 1. A plurality of cut residue portions 3a of the rectangular pads 3b remaining by dicing is shown. As schematically shown in FIG. 2A, the width of the cut residue portion 3a extending from the end portion of the semiconductor chip 62 toward the device forming region 2 and the width of the cut residue portion 3a along the end portion of the semiconductor chip 62 are both shorter than the interval between the end portions of the openings 40a of the passivation film 40 on the adjacent device pads 4.

FIG. 2B is a cross-sectional view of FIG. 2A along line A-A. A deformation layer 9 as a deformed portion by dicing is formed in the interlayer insulation film 7 exposed as the dicing cut surface that is the end surface of the semiconductor chip 62, like in the conventional art. Therefore, the cut residue portion 3a of the rectangular pad 3b lies on the unstable deformation layer 9 with a small contact area, and thus the cut residue portion 3a may come off from the interlayer insulation film 7 thereunder even under small stress in a post-process.

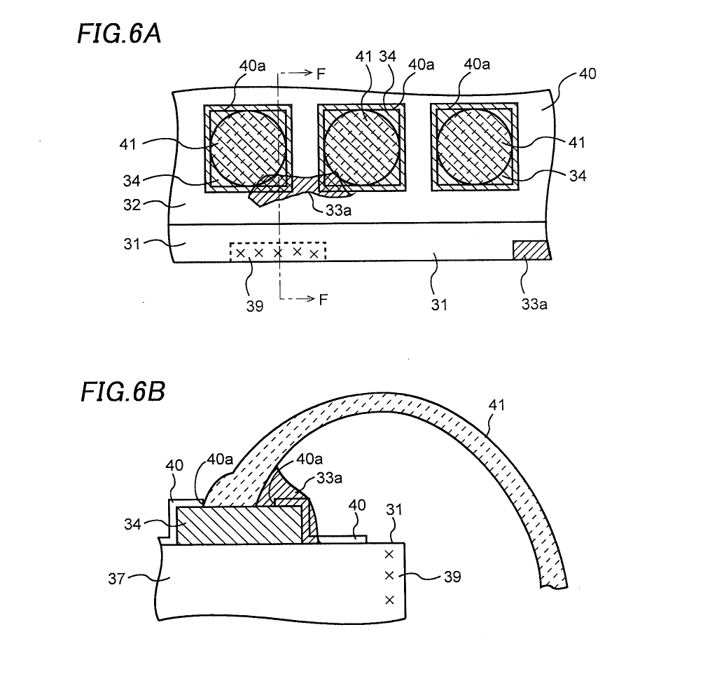

FIG. 2C schematically shows a state in which a bonding wire 10 made of a gold wire etc is wire-bonded to the device pad 4. Although not shown, the cross-sectional view including the bonding wire 10 is the same as FIG. 6B of the conventional art. FIG. 2C is different from FIG. 6A and 6B in that the length of the cut residue portion 3a coming off from the interlayer insulation film 7 is shorter than the interval between the end portions of the openings 40a of the passivation film 40 on the adjacent device pads 4.

As a result, while the cut residue portion 3a coming off from the interlayer insulation film 7 that has the deformation layer 9 in the end portion of the semiconductor chip 62 may contact one of the bonding wires 10 or contact one of the device pads 4 exposed in the openings 40a of the passivation film 40, the cut residue portion 3a does not contact both the bonding wires 10, both the device pads 4 or both of the bonding wire 10 and the device pad 4 by extending therebetween. This is because the total length of the cut residue portion 3a is shorter than the interval between the end portions of the openings 40a of the passivation film 40. Therefore, the conventional problem of affecting the yield and long range reliability of semiconductor devices is solved.

In the embodiment, when the semiconductor wafer 60 is divided into the plurality of semiconductor chips 62 by dicing along the scribe line 1, the length of each of the cut residue portions 3a of the rectangular pad 3 remaining on the end portion of the semiconductor chip 62 is shorter than the interval between the end portions of the openings 40a of the passivation film 40 on the adjacent device pads 4, thereby solving the conventional problem in the yield and long range reliability.

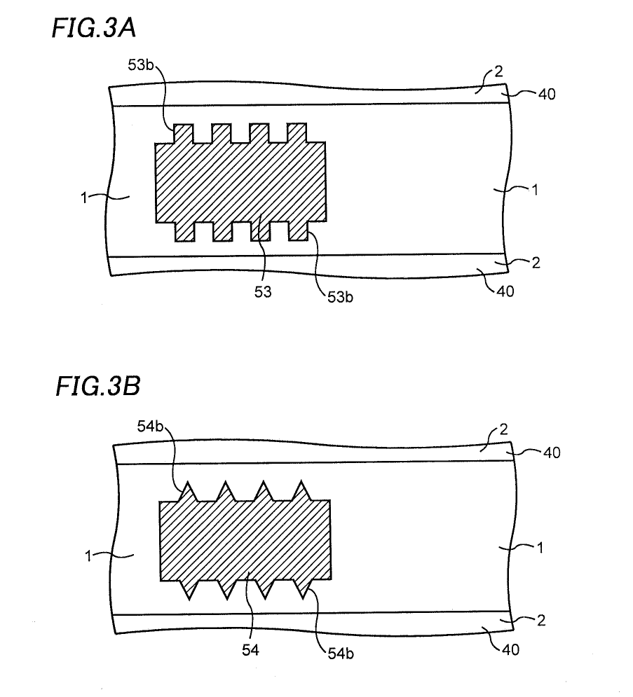

Therefore, the shape of the scribe TEG pad 3 is modifiable as long as the length of the cut residue portion 3a formed by dicing is shorter than the interval between the end portions of the openings 40a of the passivation film 40 on the adjacent device pads 4. As a modification of the embodiment, a scribe TEG pad 53 is shown in FIG. 3A and a scribe TEG pad 54 is shown in FIG. 3B. The scribe TEG pads 53 and 54 are respectively provided with protrusion portions 53b and 54b protruding from the bodies on the longer width sides.

The protrusion portions 53b and 54b are connected to the lower electrode 6 through the plug electrodes 5 made of tungsten (W) filling the via holes formed in the interlayer insulation film 7 thereunder. As a result, the total area of each of the scribe TEG pads 53 and 54 becomes large and has an advantage in a large current flow.

By dicing along the scribe line 1, all the body portion of the scribe TEG pads 53 and 54 and a portion of the protrusion portions 53b and 54b are cut away. Each of cut residue portions (not shown) of the remaining protrusion portions 53b and 54b is designed to be shorter than the interval between the end portions of the openings 40a of the passivation film 40 on the adjacent device pads 4.

A modification is not limited to FIGS. 3A and 3B as long as the length of the cut residue portion is shorter than the interval between the end portions of the openings 40a of the passivation film 40 on the adjacent device pads 4. For example, the scribe TEG pad may have semi-circle protrusion portions, semi-ellipse protrusion portions or the like that protrude from the body portion.

Even in a case of a power device employing a single-layer wiring structure instead of a multi-layer wiring structure, the same effect is obtained by forming the scribe TEG pad having the same shape as the shape shown in FIG. 3A etc.

The semiconductor device of the invention prevents a short circuit between bonding wires etc due to a cut residue portion of a scribe TEG pad coming off from an end portion of a semiconductor chip, or decreases the probability of the short circuit.

What is claimed is:

1. A semiconductor device comprising:
a semiconductor chip comprising a plurality of device pads;
a cut residue portion of a scribe TEG pad that remains on an end portion of the semiconductor chip and comes off from the end portion; and
a bonding wire connected to the device pad,
wherein the cut residue portion does not cause a short circuit between the adjacent device pads directly or through the bonding wire.

2. The semiconductor device of claim 1, wherein the device pad is covered by a passivation film having an opening exposing a portion of the device pad, and the scribe TEG pad is not covered by the passivation film.

3. The semiconductor device of claim 2, wherein the scribe TEG pad comprises a plurality of rectangular pads extending on a scribe line of a semiconductor wafer toward a device forming region before the semiconductor wafer is divided into the semiconductor chips.

4. The semiconductor device of claim 3, wherein the plurality of rectangular pads are connected to a common lower electrode through via holes formed in an interlayer insulation film under the rectangular pads.

5. The semiconductor device of claim 4, wherein the via holes are filled with plug electrodes.

6. The semiconductor device of claim 2, wherein the scribe TEG pad comprises a plurality of protrusion portions extending on a scribe line of a semiconductor wafer toward a device forming region before the semiconductor wafer is divided into the semiconductor chips.

7. The semiconductor device of claim 6, wherein a portion of the protrusion portion forms the cut residue portion.

8. The semiconductor device of claim 3, wherein a length of the cut residue portion is shorter than an interval between end portions of the openings of the passivation film on the adjacent device pads.

9. The semiconductor device of claim 1, wherein the semiconductor chip comprises a power device.
